(19) United States
(12) Patent Application Publication
(10) Pub. No.: US 2025/0285695 A1
(43) Pub. Date: Sep. 11, 2025

(54) Racetrack Memory Reading Device based on Josephson Diode Effect

(71) Applicant: MAX PLANCK GESELLSCHAFT ZUR FÖRDERUNG DER WISSENSCHAFTEN EV, München (DE)

(72) Inventors: Stewart S.P. PARKIN, Halle (DE); Keerthi Pranava SIVAKUMAR, Halle (DE); Banabir PAL, Halle (DE)

(73) Assignee: MAX PLANCK GESELLSCHAFT ZUR FÖRDERUNG DER WISSENSCHAFTEN EV, München (DE)

(21) Appl. No.: 18/858,798

(22) PCT Filed: Apr. 20, 2023
(86) PCT No.: PCT/EP2023/060246

§ 371 Date: Oct. 22, 2024

(30) Foreign Application Priority Data
Apr. 25, 2022 (EP) 22169708.9

(51) Int. Cl. G11C 19/32; G11C 11/16; G11C 19/08; H10B 61/00; H10N 60/01; H10N 60/12; H10N 60/80

(52) U.S. Cl. CPC G11C 19/32; G11C 11/161; G11C 11/1673; G11C 19/0841; H10B 61/10; H10N 60/0912; H10N 60/12; H10N 60/805

(57) ABSTRACT

The present invention relates to a reading element for a racetrack memory (RTM) that includes two superconducting electrodes (S) made of a superconducting material, which electrodes are separated by a topological metal (N) with a spin-polarized surface state, which exhibits a band inversion. The invention further relates to a method of making such a reading element as well as to its use, specifically in a racetrack memory.

The present invention relates to a superconducting reading device for racetrack memories based on the Josephson diode effect.

### BACKGROUND

Today we live in a digital world in which ever-increasing massive quantities of data are stored in the “cloud”, with concomitantly ever more energy consumption. At the same time the evolution of conventional silicon-based computing systems has reached the end of Moore's law. Novel memory and computing devices are needed that can use less energy. The leading non-volatile, high-performance memories today are, arguably the spintronic memories MRAM (Magnetoresistive Random Access Memory) and RTM (Racetrack Memory) [see e.g. U.S. Pat. No. 6,834,005; US-A 2014/204648]. MRAM like many other conventional memories, does not function well at low temperatures: MRAM requires thermal fluctuations for its operation that are suppressed at low temperatures. On the other hand, RTM is deterministic and thus, in principle, can operate even at the lowest temperatures. RTM is unique among memories in that it is a “shift register” in which data is encoded by the presence or absence of chiral domain walls and these data bits are shifted back and forth concurrently along magnetic nano-wires or “racetracks” by current pulses.

Aside from the challenge to store an ever-increasing massive quantity of data at lowest possible energy consumption, there is great interest today to develop quantum computers to perform tasks that are not possible with classical computing. Quantum computing goes beyond the concept of encoding data in memories and logic circuits as “1”s and “0”s to rather using the phase of a wavefunction that can take any value. The most advanced of these use superconducting or spin qubits and operate at ultra-low temperatures (˜10-20 mK), well below room temperature. Most research efforts are focused on the analog quantum memory and logic gates and extending their coherence times, as well as developing circuits that incorporate them. High-frequency signals (GHz) are needed to set up and read out these qubits and the number of the needed signal lines goes in tandem with the number of qubits. For practical applications vast increases in the number of qubits are needed beyond what is possible today (˜50). The heat load of this wiring and the large complexity of the needed electronics means that scaling up to large number of qubits within a dilution refrigerator is very difficult. To overcome this issue, classical control circuits are typically operated at room temperature, although significant efforts to develop cryo-CMOS that could operate at lower temperatures but above that of the quantum qubits are being spent. The significant physical separation of the digital control circuits from the analogue quantum cores results in significant latency and performance issues.

A critical bottleneck device in all of these high-performance memory devices is the reading device, which determines how and at what speed the data are read out from the memory. Specifically, in order to increase read-out speed it would be desirable to work with superconducting materials which would operate at the lowest possible resistance and, therefore, highest speed, and, at the same time consume less energy. One of the most interesting phenomena in superconductivity is the Josephson effect, a remarkable physical phenomenon wherein a junction formed from two superconducting electrodes separated by a non-superconducting barrier becomes superconducting, and the critical current of this junction can be modulated by altering the phase difference between the respective wave functions across the junction. Ever since the discovery of the Josephson effect there have been many studies to develop memory devices and logic circuits utilizing the non-linear response of a Josephson junction (JJ) as a computing and (volatile) memory element with the potential of energy-efficient, ultrafast computing. Switches based on JJs can in principle, operate at speeds in the sub-THz (picosecond) regime with very low heat dissipation. Even though current supercomputing technology requires energy for cryogenic cooling, it nevertheless offers a significant competitive advantage over CMOS technology when scaled to the exascale (i.e. about 1×10¹⁸ FLOPS (floating point operations per sec) or more).

A problem with memory devices and logic circuits utilizing the non-linear response of a Josephson junction (JJ) is that JJs are not sensitive to the direction of any applied magnetic field and, therefore, a single JJ cannot serve as a reading element in a racetrack device.

### OBJECT OF THE INVENTION

It was, therefore, an object of the present invention to provide a reading element for RTMs based on a Josephson junction (JJ) which is sensitive to the direction of the electrical current and which can operate at very high speeds in the sub-THz (picosecond) regime with very low heat dissipation.

### BRIEF DESCRIPTION OF THE INVENTION

It was found that the critical current of a Josephson junction (JJ) strongly depends on the direction of an applied magnetic field which means that a device can be tuned systematically with an external magnetic field, which in turn means that the device can be used to detect magnetic fields.

Accordingly, the present invention concerns a reading element for RTMs, which comprises two superconducting electrodes(S) made of a superconducting material, which electrodes are separated by a topological metal (N) with a spin-polarized surface state, which exhibits a band inversion, preferably a two-dimensional, centrosymmetric, type-II, Dirac semi-metal, more preferred a member of the family of column-10 transition metal ditellurides, most preferred by NiTe₂.

### BRIEF DESCRIPTION OF THE DRAWINGS

FIG. 1 is an Illustration of a complete racetrack memory device including a racetrack layer (1), a write element (2), a read head (3) and a shift element (4) to move magnetic bits along the racetrack.

FIG. 2a is a Schematic of an S-N-S device. (N: Normal. S: Superconductor) formed from Nb—NiTe₂—Nb.

FIG. 2b is the Crystal structure of NiTe₂ shown along two different crystal directions.

FIG. 2c is an image of a JJ device

FIG. 2d shows Voltage vs current (V-I) characteristics showing a dramatic difference in the critical Josephson current I_{c} for positive and negative current directions.

FIG. 2e shows the rectification effect showing a JDE.

FIG. 2f shows the Magnetic field dependent evolution of the non-reciprocal current ΔI_{c}, showing a sign reversal.

FIG. 3: Electrical characterization of the Josephson junction devices.

FIG. 3a: Current (I)-voltage (V) curves for three Josephson junctions with superconducting electrode separations, d=120, 350 and 580 nm.

FIG. 3b: Dependence of the normal state resistance (Rₙ) on d for three devices.

FIG. 3c: Dependence of the critical voltage on d.

FIG. 4: NiTe₂ JJ device and the observation of a Josephson Diode effect.

FIG. 4b-c: Schematic illustrations of the Josephson device and the corresponding fermi surface. In the absence of both in-plane magnetic field and the Josephson current, the weak link contains spin-orbit coupled helical surface states, as schematically shown in the bottom panel of FIG. 4b. As discussed in the text, in the presence of an in-plane magnetic field, the helical surface state acquires a momentum shift qₓ=qₓ (B_{y}), as shown in FIG. 4c. When the Josephson current flows through the junction (l+ corresponds to the Josephson current flowing in the +x direction), the critical current is different depending on its direction.

FIG. 4d: Voltage as a function of temperature at zero field for a JJ device with d=350 nm that shows two transitions at T_{SC} and T_{J}. Inset of FIG. 4d shows the variation of T_{SC} and T_{J} with d.

FIG. 4e: I-V curve of a JJ device with d=350 nm at 20 mK and an in-plane magnetic field B_{y}=20 mT showing a large non-reciprocal critical current, I_{c-}| and I_{c+}.

FIG. 4f: Rectification effect observed using currents between |I_{c-}| and I_{c+} for the same JJ device at 20 mK and B_{y}=20 mT.

FIG. 5 relates to the dependence of ΔI_{c} on in-plane magnetic field, angle and temperature.

FIG. 5a: Variation of ΔI_{c} as a function of By at selected temperatures in a JJ device with d=350 nm.

FIGS. 5b-c: Dependence of ΔI_{c} as a function of in-plane magnetic field applied at different angles with respect to the current direction and the corresponding color contour map for the same device. θ=0°/±180° (and) ±90° correspond to the in-plane magnetic field being perpendicular (and parallel) to the current direction.

FIG. 5d: Dependence of ΔI_{c} on temperature for B_{y}=12 mT for the same device. Inset shows a quadratic dependence (T−T_{J})² of the ΔIc on temperature close to T_{J}.

FIGS. 5e-f: Calculation of the dependence of ΔI_{c} on the angle of the in-plane magnetic field and the corresponding color map, performed from eq. (7) at B_{d}=22 mT and B_{c}=45 mT.

### DETAILED DESCRIPTION OF THE INVENTION

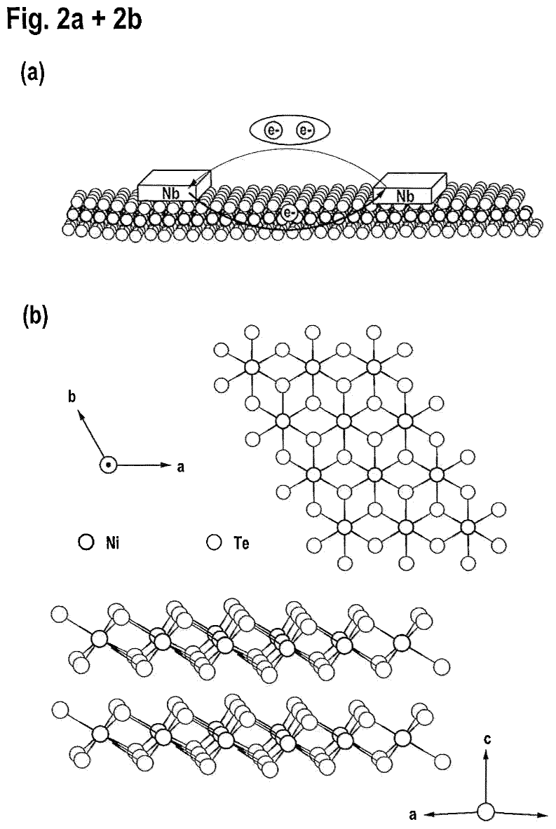

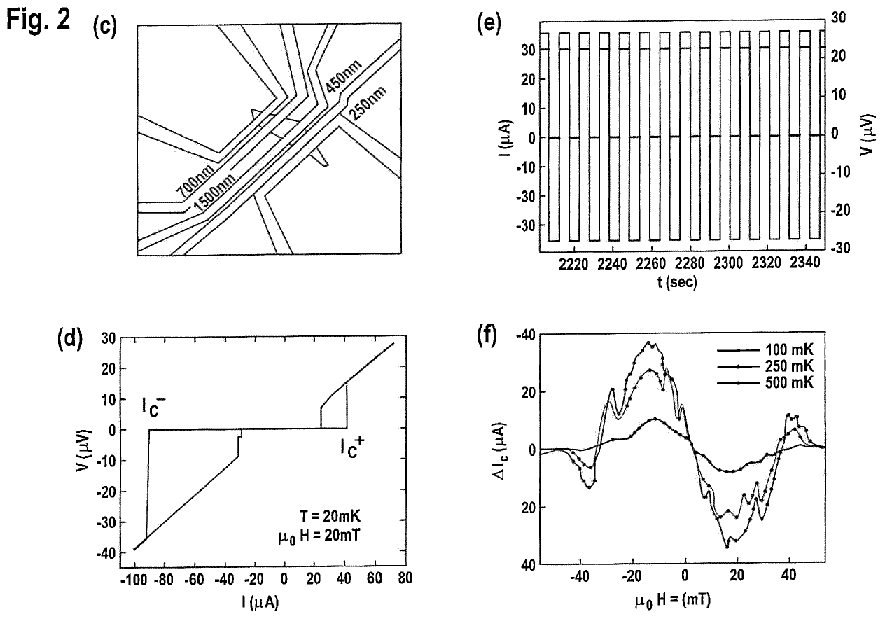

The present invention builds upon a non-reciprocal superconducting phenomenon, the so-called Josephson Diode Effect (JDE). The inventors have found that the critical current for proximity induced superconductivity in layers of a type-II Dirac semi-metal, NiTe₂ (see FIG. 2a, b), is distinct for current flowing in opposite directions (see FIG. 2d). The critical current depends upon the direction in which the current flows in the presence of small magnetic fields. The JDE can be tuned systematically with an external magnetic field, so that the device can be used to detect magnetic fields (see FIG. 2f). Accordingly, a JD in proximity to a perpendicularly magnetized magnetic bit on a racetrack can serve as the reading element of the memory, since the critical current strongly depends on the direction of the magnetic field. Thus, since the Josephson Diode Effect is asymmetric with respect to the direction of the stray magnetic field, when a suitable current is pulsed, one magnetic domain would produce a zero-voltage superconducting state across the JD while the other domain would produce a finite non-zero voltage across the JD.

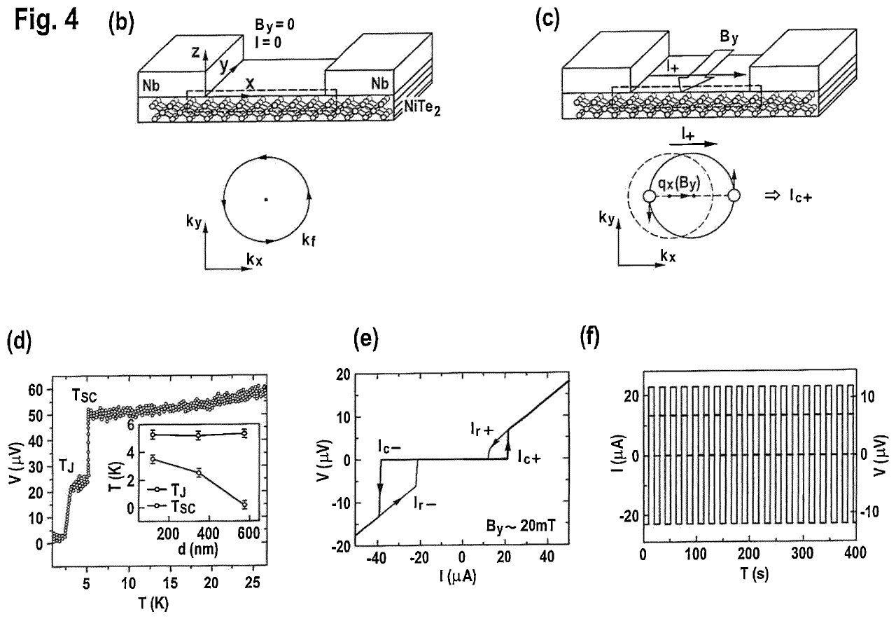

The reading element for RTMs according to the present invention comprises two superconducting electrodes (S) made of a superconducting material, which electrodes are separated by a topological metal (N) with a spin-polarized surface state which exhibits a band inversion as shown in FIG. 2(c). The lateral spacing between the superconducting electrodes can be varied from about 10 nm to about 1 micron. It is to be understood, that the “separation” of the two electrodes means the spatial distance between the two electrodes, wherein the space between the two electrodes may or may not be filled with the topological metal (N); i.e. it includes the design, where the two electrodes are deposited onto the surface of the topological metal (N) spaced apart by the lateral spacing of about 10 nm to about 1 micron (see FIG. 4b-c).

Preferably the topological metal is a two-dimensional, centrosymmetric, type-II Dirac semi-metal which exhibits a band inversion. The metal is preferably selected from members of the family of column-10 transition metal ditellurides (Ni, Pd, Pt). All members in this family (NiTe₂, PdTe₂, PtTe₂) are type-II Dirac semimetals and host spin-polarized surface states. A centrosymmetric type-II Dirac semimetal preserves inversion symmetry, and should, therefore, not exhibit a JDE. It is, thus, believed that topological surface or interface states are responsible for the observed properties. Indeed, NiTe₂ exhibits unique spin-polarized surface states.

The superconducting material of the superconducting electrodes(S) preferably is a known bulk topological superconductor. Typical superconducting materials which can be used for this purpose e are known and e.g. described in https://en.wikipedia.org/wiki/List of super-conductors, examples of which are: Al, Be, Bi, Ga, Hf, α-La, β-La, Mo, Nb, Os, Pb, Re, Rh, Ru, Sn, Ta, α-Th, Ti, V, α-W, β-W, Zn, Zr, FeB₄, InN, In₂O₃, LaB₆, MgB₂, Nb₃Al, NbC₁₋ₓNₓ, Nb₃Ge, NbO, NbN, Nb₃Sn, NbTi, TiN, V₃Si, YB₆, ZIN, ZrB₁₂, YBCO (Yttrium barium copper oxide), BSCCO (Bismuth strontium calcium copper oxide), HBCCO (Mercury bismuth calcium copper oxide), preferably Nb or NbN.

The lateral spacing between the superconducting electrodes can be varied from about 10 nm to about 1 micron.

In the racetrack memory device the reading element of the present invention is arranged proximal to the racetrack magnetic layers, preferably 0.5 nm to 100 nm from the racetrack magnetic layers, preferably 0.5 nm to 10 nm, or more preferably 0.5 to 5 nm from the these layers. This proximal distance is preferably accomplished with a separating layer. The separating layer can be selected from a metal with low spin-orbit coupling, e.g. Al, Cu or Be.

### Manufacture of the JJ Device

First a thin layer of the Dirac semi-metal e.g. NiTe₂ is exfoliated from a bulk crystal of the Dirac semi-metal and placed on a substrate e.g. SiO₂. Then the superconducting contacts are fabricated e.g. using an electron beam lithography based method. Before exposure, each substrate is spin coated e.g. with an AR-P 679.03 resist followed by annealing at elevated temperatures, e.g. 150° C. After electron beam exposure and subsequent development, contact electrodes are formed from sputter-deposited superconductor, e.g. tri-layers of 2 nm Ti/30 nm Nb/20 nm Au to thereby create the Josephson junction (JJ) devices.

The present invention is illustrated by the following examples.

### Examples

Thin NiTe₂ flakes were exfoliated from a high quality NiTe₂ single crystal (from HQ Graphene company) using a standard scotch tape exfoliation technique and placed on a Si (100) substrate with a 280 nm thick SiO₂ on top. The exfoliation was carried out in a glove box under a nitrogen atmosphere, with water and oxygen levels each below 1 ppm. The thinnest flakes were identified from their optical contrast in an optical microscope and used subsequently to prepare devices. X-ray photoelectron spectroscopy (XPS) was performed on the exfoliated flakes to verify the composition. Angle resolved photoelectron spectroscopy (ARPES) measurements were carried out on the single crystal after in-situ cleaving.

All the devices used were fabricated using an electron beam lithography based method. Before exposure, each substrate was spin coated with an AR-P 679.03 resist at 4000 rpm for 60 sec followed by annealing at 150° C. for 60 sec. After electron beam exposure and subsequent development, contact electrodes were formed from sputter-deposited tri-layers of 2 nm Ti/30 nm Nb/20 nm Au for the Josephson junction (JJ) devices.

Electrical transport measurements were performed in a Bluefors LD-400 dilution refrigerator with a base temperature of 20 mK and equipped with high frequency electronic filters (from QDevil Aps). Angle-dependent magnetic field measurements were carried out using a 2D superconducting vector magnet integrated within the Bluefors system. A small consistent offset in the magnetic field, of the order of ˜1.5 mT, was observed while sweeping the magnetic field due to likely flux trapping within the superconducting magnet coils. Direct current-voltage characteristics of the JJ devices were measured using a Keithley 6221 current source and a Keithley 2182A nanovoltmeter. Differential resistance measurements were performed using a Zurich Instruments MFLI lock-in amplifier with a multi-demodulator option using a standard low-frequency (3-28 Hz) lock-in technique. The critical currents for the Fraunhofer pattern were measured in combination with a Keithley 2636B voltage source to sweep the DC bias.

NiTe₂ is a layered van der Waals materials which can be easily exfoliated. It crystallizes in a trigonal crystal structure with the space group P_{3̅m1}. The crystal structure is comprised of NiTe₂ tri-layers stacked along the c axis, each tri-layer composed of a Ni sheet sandwiched between two Te sheets. The crystal structure of NiTe₂ along two crystallographic directions is shown in FIG. 2b.

Atomic force microscopy (AFM) measurements were performed on the devices to measure both the thicknesses of the NiTe₂ flakes as well as to estimate the distance between the superconducting electrodes in the Josephson junction devices. A typical AFM image of a device is shown in the inset of FIG. 2c

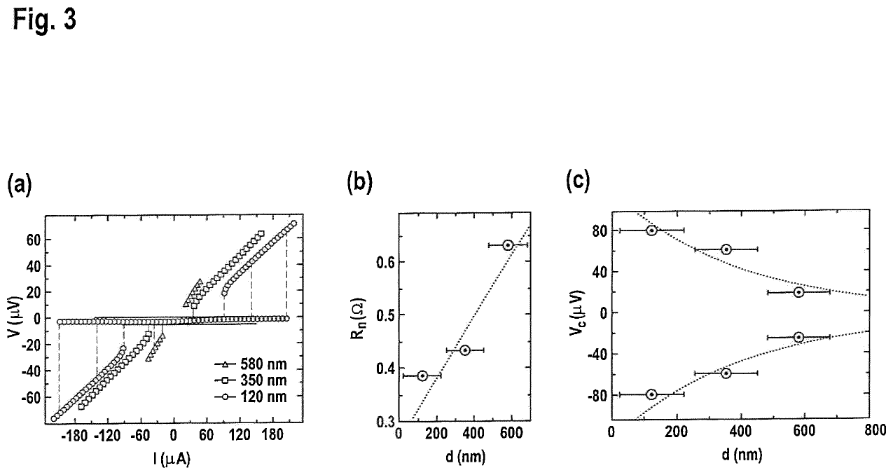

FIG. 3a shows current (I)-voltage (V) curves for three Josephson junctions with superconducting electrode separations, d=120, 350 and 580 nm at T=20 mK in the absence of any magnetic field. It can be seen clearly that there is no diode effect in the absence of a magnetic field. Large hysteresis in the I-V curves suggest that the devices are in the underdamped regime. With increasing d, the normal state resistance (Rₙ) determined from the slope of the I-V curve increases (FIG. 3b) and the corresponding critical current (I_{c}) decreases (FIG. 3a), as expected for a proximity-induced Josephson junction. The fitting of the d dependence of the characteristic voltage (V_{c}=I_{c}Rₙ) using an exponential dependence

$$∼ {e}^{( - \frac{d}{ξ} )}$$

shows that the characteristic decay length (ξ) in this device is ˜414 nm (FIG. 3c).

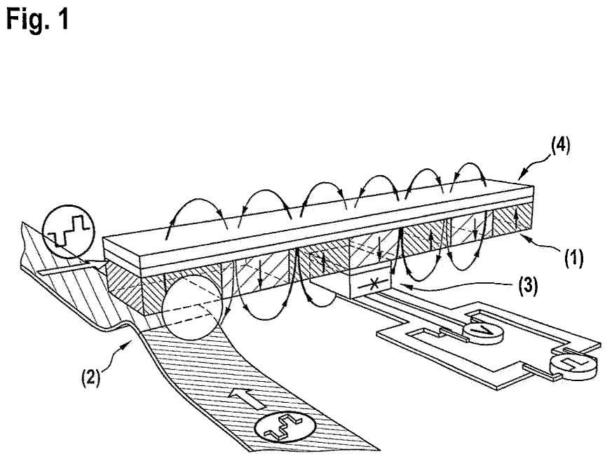

A schematic of the JJ device is shown in FIG. 4b-c, in the absence and presence of Josephson current, respectively, where x is parallel to the current direction and z is the out-of-plane direction. The temperature dependence of the resistance of the device with d=350 nm (FIG. 1d) shows two transitions: the first transition (T_{SC}) at ˜5.3 K is related to the superconducting electrodes. A second transition (T_{J}) takes place at a lower temperature when the device enters the Josephson transport regime such that a supercurrent flows through the NiTe₂ layer. The dependence of both T_{SC} and T_{J} as a function of the edge-to-edge separation, d, between the electrodes is shown in the inset of FIG. 4d. While T_{SC} is independent of d, T_{J} decreases with increasing d, which corroborates that T_{J} corresponds to the superconducting proximity transition of the JJ device.

To observe the JDE (see illustration in FIG. 4b-c), current versus voltage (I-V) measurements were carried out as a function of temperature and magnetic field. FIG. 4e shows I-V curves in the presence of an in-plane magnetic field B_{y}˜20 mT perpendicular to the direction of the current for the device with d=350 nm. The device exhibits four different values of the critical current with a large hysteresis indicating that the JJs are in the underdamped regime. During the negative to positive current sweep (from −50 μA to +50 μA) the device shows two critical currents Iᵣ₋ and I_{c+} whereas during a positive to negative current sweep (from +50 μA to −50 μA) the device exhibits two other critical currents Iᵣ₊ and I_{c-}. The critical currents I_{c-} and I_{c+}, correspond to the critical values of the supercurrent when the system is still superconducting. For small magnetic fields, the absolute magnitude of I_{c-} is clearly much larger than that of I_{c+} (FIG. 4e). For zero field data I_{c+}=|I_{c}-|. These different values of I_{c+} and |I_{c-}| mean that when the absolute value of the applied current lies between I_{c+} and |I_{c-}|, the system will behave as a superconductor for the current along one direction while a normal dissipative metal for the current along the opposite direction. This difference demonstrates a clear rectification effect, as shown in FIG. 4f, that occurs for currents which are larger than I_{c+} but smaller than |I_{c-}|.

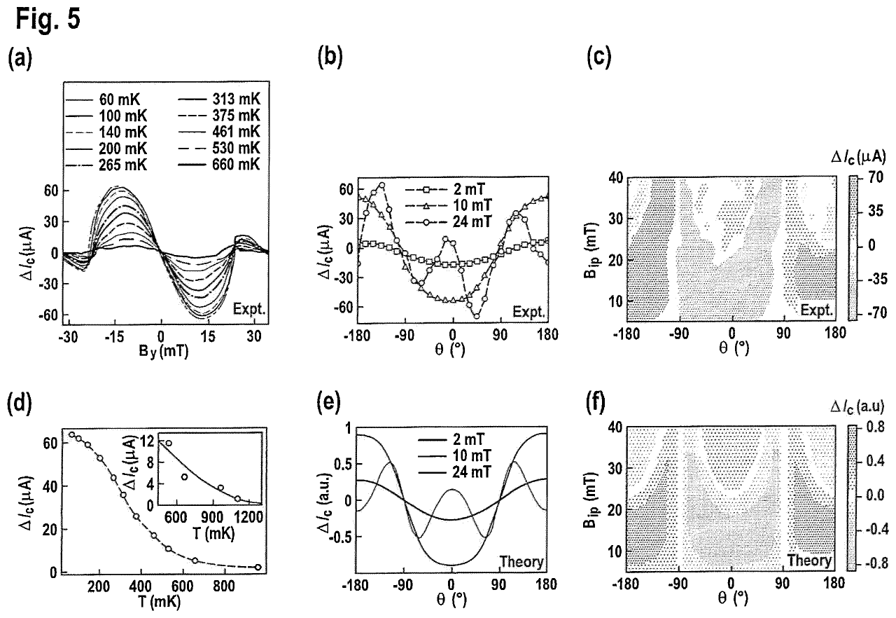

To probe the origin of the JDE, the evolution of ΔI_{c} (ΔI_{c}≡I_{c+}−|I_{c-}|) was examined as a function of applied in-plane magnetic field at various temperatures and angles with respect to the current direction. The dependence of ΔI_{c} on B_{y} (field parallel to the y axis and perpendicular to the current) at different temperatures demonstrates that ΔI_{c} is antisymmetric with respect to B_{y} (FIG. 5a). At 60 mK, ΔI_{c} exhibits a maximum and a minimum value at B_{y}=∓12 mT, respectively (FIG. 5a) and the ratio [symbol] is as large as 60%, where

$$〈 {T}_{c} 〉 = \frac{( {I}_{c +} + \vert {I}_{c -} \vert )}{2} .$$

Such a large magnitude of [symbol] at a low magnetic field (˜12 mT) makes this system unique, as compared to previous reports where either the magnitude of [symbol] was found to be small, or a large magnetic field was required to observe a significant effect. Also, multiple sign reversals were observed in ΔI_{c} when Bᵢₚ is increased, a previously unobserved and interesting dependence.

The dependence of ΔI_{c} on the direction of the in-plane magnetic field with respect to the current is shown in FIG. 5b-c, for several field strengths. At small fields, |ΔI_{c}| is largest when the field is perpendicular to the current (θ=0°/±180°, where θ is the in-plane angle measured with respect to the y-axis) and vanishes when the field and current are parallel (θ=±90°). With regard to the temperature dependence of ΔI_{c}, it was found that the magnitude of ΔI_{c} increases monotonically as the temperature is lowered (FIG. 5a). For a quantitative understanding, the temperature dependence of ΔI_{c} for B_{y}=12 mT (the field at which ΔI_{c} takes the largest value) is shown in FIG. 5d. At temperatures near T_{J}, the variation of ΔI_{c} with temperature can be well fitted by the equation ΔI_{c}=α(T−T_{J})² (inset of FIG. 5d).

FIGS. 5e-f show the dependencies of ΔI_{c} on the magnitude of B_{y} and the direction of the in-plane magnetic field as obtained from our phenomenological model, where B_{c}=45 mT and B_{d}˜22 mT was used. In order to explain the angular direction dependence, it was taken into account that the non-reciprocal part of the current is proportional only to the x-component of the momentum shift (qₓ) that is proportional to the B_{y}(=Bᵢₚ cos θ) component of the in-plane magnetic field. In FIG. 5f it is shown that in each domain

$$- \frac{π}{2} + π n < θ < \frac{π}{2} + π n ,$$

the sign reversal of ΔI_{c} occurs where the condition

$$sin ( π \frac{{B}_{ip} cos θ}{{B}_{d}} ) = 0$$

is fulfilled, which one can see clearly in FIG. 5c. Thus, this model successfully captures the main features of the JDE as seen in the experimental data.

In summary, these data show that a JJ device involving a type-II Dirac semimetal NiTe₂ exhibits a large non-reciprocal critical current. The effect is antisymmetric with respect to the magnetic field perpendicular to the current direction and exhibits a (T−T_{J})² temperature dependence.

1. A reading element for a racetrack memory (RTM) comprising two superconducting electrodes (S) made of a superconducting material, which electrodes are separated by a topological metal (N) with a spin-polarized surface state, which exhibits a band inversion.

2. The reading element according to claim 1, wherein the topological metal is a two-dimensional, centrosymmetric, type-II, Dirac semi-metal.

3. The reading element according to claim 1, wherein the topological metal is NiTe₂, PdTe₂ or PtTe₂.

4. The reading element according to claim 3, wherein the topological metal is NiTe₂.

5. The reading element according to claim 1, wherein the superconducting material of the superconducting electrodes(S) are selected from: Al, Be, Bi, Ga, Hf, α-La, β-La, Mo, Nb, Os, Pb, Re, Rh, Ru, Sn, Ta, α-Th, Ti, V, α-W, β-W, Zn, Zr, FeB₄, InN, In₂O₃, LaB₆, MgB₂, Nb₃Al, NbC₁₋ₓNₓ, Nb₃Ge, NbO, NbN, Nb₃Sn, NbTi, TiN, V₃Si, YB₆, ZrN, ZrB₁₂, YBCO Yttrium barium copper oxide (YBCO), Bismuth strontium calcium copper oxide (BSCCO), or Mercury bismuth calcium copper oxide (HBCCO).

6. The reading element according to claim 1, wherein the lateral spacing between the superconducting electrodes is from about 10 nm to about 1 micron.

7. A racetrack memory (RTM) device comprising a reading element according to claim 1.

8. The racetrack memory (RTM) device according to claim 7, wherein the reading element is arranged at a proximal distance to the racetrack of 0.5 nm to 100 nm.

9. The racetrack memory (RTM) device according to claim 8, wherein the proximal distance is accomplished with a separating layer and the separating layer material is selected from a metal with low spin-orbit coupling.

10. A method of manufacturing a reading element according to claim 1, comprising exfoliating a thin layer of a Dirac semi-metal from a bulk crystal of the Dirac semi-metal, placing the exfoliated thin layer on a substrate, then fabricating two superconducting contacts using electron beam lithography.

11. An electronic switch comprising a reading element according to claim 1.

12. A quantum computer comprising a reading element according to claim 1.

13. The reading element according to claim 5, wherein the superconducting material of the superconducting electrodes(S) is Nb or NbN.

14. The racetrack memory (RTM) device according to claim 8, wherein the reading element is arranged at a proximal distance to the racetrack of 0.5 to 10 nm.

15. The racetrack memory (RTM) device according to claim 8, wherein the reading element is arranged at a proximal distance to the racetrack of 0.5 to 5 nm.

16. The racetrack memory (RTM) device according to claim 9, wherein the separating layer material is selected from Al, Cu or Be.
